(19) United States
(12) Patent Application Publication
(10) Pub. No.: US 2015/0223318 A1
(43) Pub. Date: Aug. 6, 2015

(54) MULTILAYER WIRING BOARD

(71) Applicant: IBIDEN CO., LTD., Ogaki-shi (JP)

(72) Inventor: Hajime SAKAMOTO, Ogaki-shi (JP)

(73) Assignee: IBIDEN CO., LTD., Ogaki-shi (JP)

(21) Appl. No.: 14/610,245

(22) Filed: Jan. 30, 2015

(30) Foreign Application Priority Data
Jan. 31, 2014 (JP) 2014-017796

(51) Int. Cl. H05K 1/02; H05K 1/18; H05K 1/11

(52) U.S. Cl. CPC H05K 1/0203; H05K 1/0298; H05K 1/112; H05K 1/181

(57) ABSTRACT

A multilayer wiring board includes a first insulating layer, first conductor patterns formed on the first insulating layer, and a wiring structure formed on the first insulating layer and including a heat sink and second conductor patterns formed on the heat sink such that the wiring structure is positioned adjacent to the first conductor patterns on the first insulating layer.

### CROSS-REFERENCE TO RELATED APPLICATIONS

The present application is based upon and claims the benefit of priority to Japanese Patent Application No. 2014-017796, filed Jan. 31, 2014, the entire contents of which are incorporated herein by reference.

### BACKGROUND OF THE INVENTION

1. Field of the Invention

The present invention relates to a multilayer wiring board. Specifically, the present invention relates to a multilayer wiring board that includes a heat sink.

2. Description of Background Art

Japanese Patent Publication No. 2013-214578 describes a multilayer wiring board which includes an auxiliary wiring board and a main wiring board to which the auxiliary wiring board is affixed, a wiring pattern being formed at a high density on an insulating resin layer of the auxiliary wiring board with glass as a support plate. In the multilayer wiring board, the auxiliary wiring board, on which high density wiring can be formed, is provided at a portion where two semiconductor chips (MPU and DRAM) are connected and at a portion connecting electrodes of these chips. The entire contents of this publication are incorporated herein by reference.

### SUMMARY OF THE INVENTION

According to one aspect of the present invention, a multilayer wiring board includes a first insulating layer, first conductor patterns formed on the first insulating layer, and a wiring structure formed on the first insulating layer and including a heat sink and second conductor patterns formed on the heat sink such that the wiring structure is positioned adjacent to the first conductor patterns on the first insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a multilayer wiring board according to an embodiment of the present invention;

FIG. 1B is a plan view of the multilayer wiring board shown in FIG. 1A;

FIG. 2 is an expanded view of a wiring structure of the multilayer wiring board shown in FIG. 1, and of a peripheral portion of one end thereof;

FIG. 3 is a cross-sectional view of a modified example of a wiring layer of the wiring structure of the multilayer wiring board shown in FIG. 1;

FIG. 4 is a cross-sectional view of a state in which a semiconductor element is connected to the multilayer wiring board according to the embodiment of the present invention;

FIG. 5A is an expanded view of a cross-section of a modified example of a laminate structure of the multilayer wiring board according to the embodiment of the present invention;

FIG. 5B is an expanded view of a cross-section of another modified example of the laminate structure of the multilayer wiring board according to the embodiment of the present invention;

FIG. 5C is an expanded view of a cross-section of still another modified example of the laminate structure of the multilayer wiring board according to the embodiment of the present invention;

FIG. 6A is an explanatory diagram of an exemplary wiring structure positioning device according to the embodiment of the present invention;

FIG. 6B is an explanatory diagram of another exemplary wiring structure positioning device according to the embodiment of the present invention;

FIG. 7A is a plan view of an exemplary wiring structure positioning device according to the embodiment of the present invention;

FIG. 7B is a plan view of another exemplary wiring structure positioning device according to the embodiment of the present invention;

FIG. 7C is a plan view of still another exemplary wiring structure positioning device according to the embodiment of the present invention;

FIG. 8 is a cross-sectional view of an example including two wiring structures of the multilayer wiring board according to the embodiment of the present invention;

FIG. 9A is an explanatory diagram of each process in a method for manufacturing a wiring portion of the wiring structure according to the embodiment of the present invention;

FIG. 9B is an explanatory diagram of each process in the method for manufacturing the wiring portion of the wiring structure according to the embodiment of the present invention;

FIG. 9C is an explanatory diagram of each process in the method for manufacturing the wiring portion of the wiring structure according to the embodiment of the present invention;

FIG. 9D is an explanatory diagram of each process in the method for manufacturing the wiring portion of the wiring structure according to the embodiment of the present invention;

FIG. 9E is an explanatory diagram of each process in the method for manufacturing the wiring portion of the wiring structure according to the embodiment of the present invention;

FIG. 9F is an explanatory diagram of each process in the method for manufacturing the wiring portion of the wiring structure according to the embodiment of the present invention;

FIG. 9G is an explanatory diagram of each process in the method for manufacturing the wiring portion of the wiring structure according to the embodiment of the present invention;

FIG. 10A is an explanatory diagram of each process following formation of the wiring portion in the method for manufacturing the wiring structure according to the embodiment of the present invention;

FIG. 10B is an explanatory diagram of each process following formation of the wiring portion in the method for manufacturing the wiring structure according to the embodiment of the present invention;

FIG. 10C is an explanatory diagram of each process following formation of the wiring portion in the method for manufacturing the wiring structure according to the embodiment of the present invention;

FIG. 11A is an explanatory diagram of each process in a method for manufacturing the multilayer wiring board according to the embodiment of the present invention;

FIG. 11B is an explanatory diagram of each process in the method for manufacturing the multilayer wiring board according to the embodiment of the present invention;

FIG. 11C is an explanatory diagram of each process in the method for manufacturing the multilayer wiring board according to the embodiment of the present invention;

FIG. 11D is an explanatory diagram of each process in the method for manufacturing the multilayer wiring board according to the embodiment of the present invention;

FIG. 11E is an explanatory diagram of each process in the method for manufacturing the multilayer wiring board according to the embodiment of the present invention;

FIG. 11F is an explanatory diagram of each process in the method for manufacturing the multilayer wiring board according to the embodiment of the present invention;

FIG. 11G is an explanatory diagram of each process in the method for manufacturing the multilayer wiring board according to the embodiment of the present invention; and

FIG. 11H is an explanatory diagram of each process in the method for manufacturing the multilayer wiring board according to the embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

The term “insulating layer” used in the present description includes not only an insulating layer laminated on a build-up layer of a build-up multilayer wiring board, but also an insulating base material forming a core substrate of the build-up multilayer wiring board. In the following description, a layer proximate to the core substrate of the multilayer wiring board of an embodiment of the present invention is referred to as a bottom layer or an inner layer, and a layer far from the core substrate is referred to as a top layer or outer layer. In addition, one surface of the core substrate is referred to as a first surface (F1), while another surface is referred to as a second surface (F2).

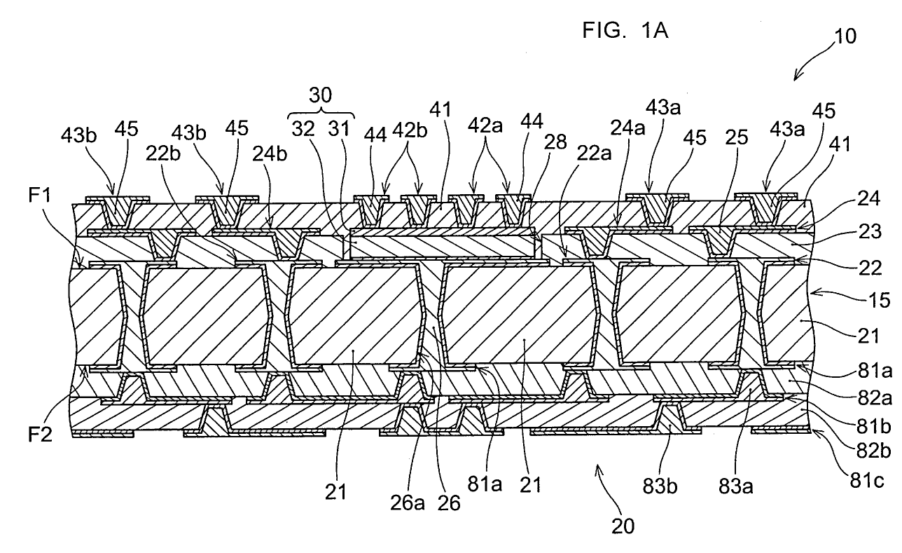

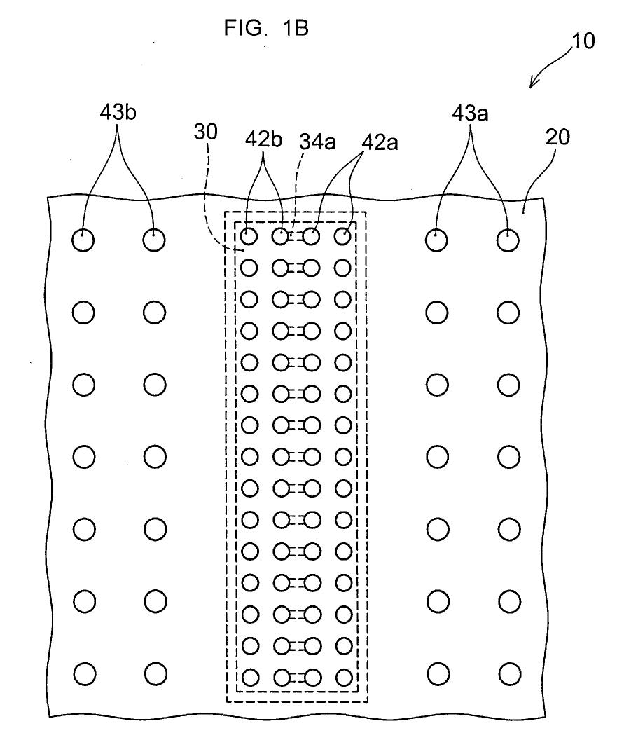

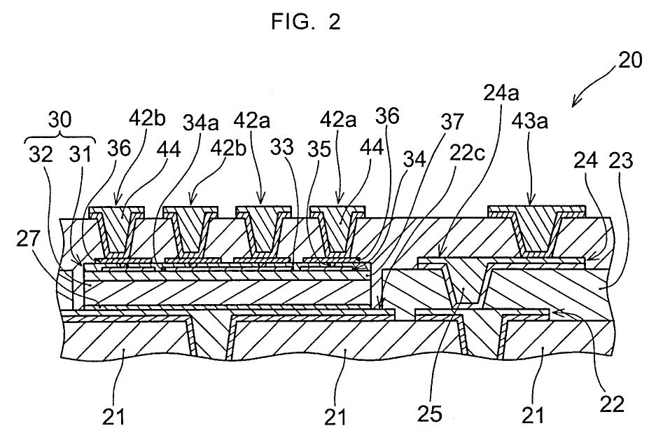

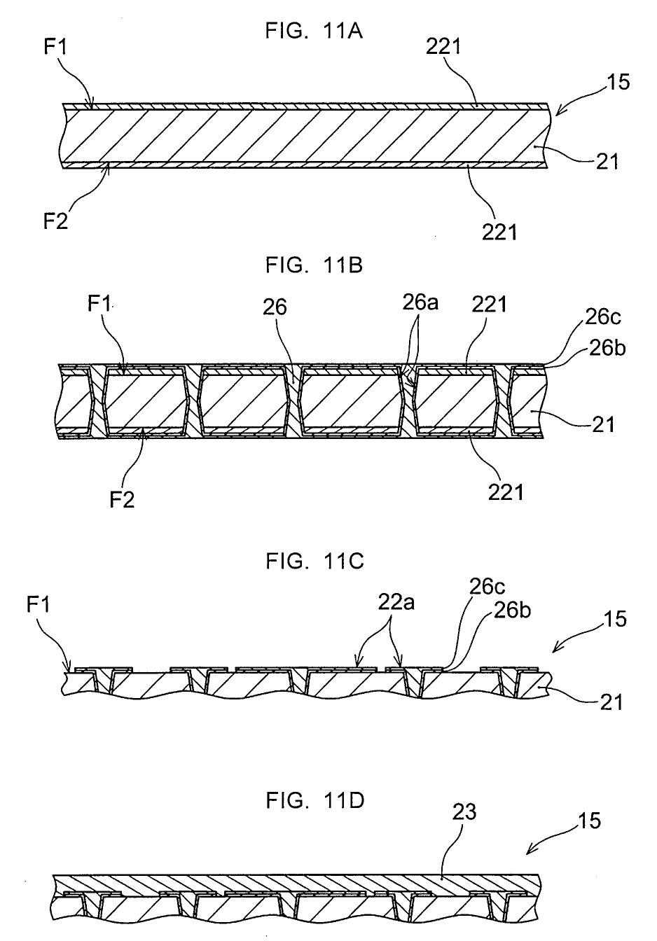

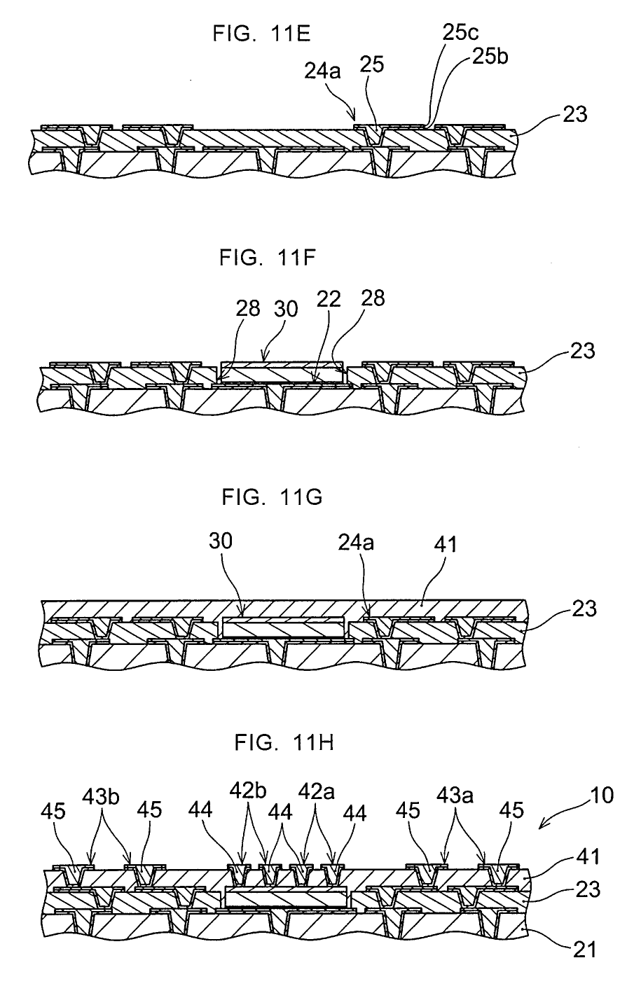

As shown in FIG. 1A, a multilayer wiring board (10) according to an embodiment of the present invention includes a main wiring board (20) and an auxiliary wiring board (30). In the present embodiment, the main wiring board (20) is a build-up multilayer wiring board. The main wiring board (20) includes a first insulating layer (21) and a first conductor pattern (22a) formed on the first insulating layer (21). The first insulating layer (21) may be an insulating layer within the core substrate (15), as shown in FIG. 1A, or may be an insulating layer within a build-up layer. As shown in FIG. 1A, in the present embodiment, the first conductor pattern (22a) is formed on a first conductor layer (22) provided above the first insulating layer (21). As shown in FIG. 2, the auxiliary wiring board (30) is formed by a wiring structure (30) which includes a heat sink (32) provided above the first insulating layer (21) so as to extend parallel to the first conductor pattern (22a), and a wiring portion (31) formed on the heat sink (32). As noted above, in the present embodiment the main wiring board (20) is a build-up multilayer wiring board having a core substrate; however, a main wiring board according to the present invention is not limited to this and may also be a core-less substrate not having a core substrate. In such a case, the first insulating layer (21) may be an insulating layer forming a build-up layer. Moreover, each conductor layer and conductor pattern of the multilayer wiring board according to the present embodiment is formed to include an electroless plating film and an electroplating film formed on the electroless plating film. Therefore, in each of the drawings (cross-sectional views), each conductor layer and each conductor pattern are illustrated by a two-layer structure. In addition, the first conductor layer (22) and a conductor layer (81a) further include copper foil on the core substrate (15); however, with the exception of FIGS. 11A and 11B, a depiction of the copper foil is omitted.

As shown in FIG. 1A, in the present embodiment, the main wiring board (20) further includes a third insulating layer (23) provided on the first insulating layer (21) and on the first conductor pattern (22a); a third conductor layer (24) provided on the third insulating layer (23); and a second via conductor (25) passing through the third insulating layer (23) and connecting the first conductor layer (22) and the third conductor layer (24). The wiring structure (auxiliary wiring board) (30) is provided within an opening (28) provided to the third insulating layer (23). A conductor pattern forming an electric circuit; a planar conductor pattern (beta pattern); or a conductor pattern forming a connection wiring, pad, or land, for example, is formed on the first conductor layer (22) and the third conductor layer (24). In the present embodiment, the first conductor pattern (22a) is formed on the first conductor layer (22) on a right side of the wiring structure (30) in FIG. 1A, while a fourth conductor pattern (22b) is formed on a left sight of the wiring structure (30) in FIG. 1A. In addition, third conductor patterns (24a, 24b) are respectively formed on two sides of the third conductor layer (24) with the wiring structure (30) therebetween.

As shown in FIG. 2, in the present embodiment, the wiring portion (31) of the wiring structure (30) includes a fifth insulating layer (37) formed on a front surface of the heat sink (32); a second conductor layer (34) formed on the fifth insulating layer (37); a second insulating layer (33) provided so as to cover the second conductor layer (34); a first via conductor (35) formed so as to pass through the second insulating layer (33) and connect with the second conductor layer (34); and a conductor pad (36) formed so as to connect with the first via conductor (35). A second conductor pattern (34a) formed by a planar conductor pattern, or by a connection wiring, pad, or land, for example, is formed on the second conductor layer (34). Polyimide, phenolic resin, polybenzoxazolic resin, or the like is used as a material for the second insulating layer (33) and the fifth insulating layer (37). However, the material is not limited to these.

As shown in FIG. 1A, in the present embodiment, a fourth insulating layer (41) is provided on the wiring structure (30) and the third conductor layer (24). First mounting pads (42a, 42b) and second mounting pads (43a, 43b) are provided on the fourth insulating layer (41). As shown in FIG. 1B, in the present embodiment, an interval between the first mounting pads (42a) and an interval between the first mounting pads (42b) are narrower than an interval between the second mounting pads (43a) and an interval between the second mounting pads (43b). In addition, as shown in FIG. 1A, third via conductors (44, 45) are provided within the fourth insulating layer (41). A top layer side of the third via conductor (44) is connected to the first mounting pads (42a, 42b). Meanwhile, as shown in FIG. 2, a bottom layer side of the third via conductor (44) is connected to the conductor pad (36) of the wiring structure (30). Similarly, the second mounting pads (43a, 43b) are connected by the third via conductor (45) to the third conductor patterns (24a, 24b), respectively, which are formed on the third conductor layer (24). In addition, the second mounting pads (43a, 43b) are electrically connected via the third conductor layer (24) and the second via conductor (25) to the first conductor pattern (22a) and the fourth conductor pattern (22b), respectively, formed on the first conductor layer (22).

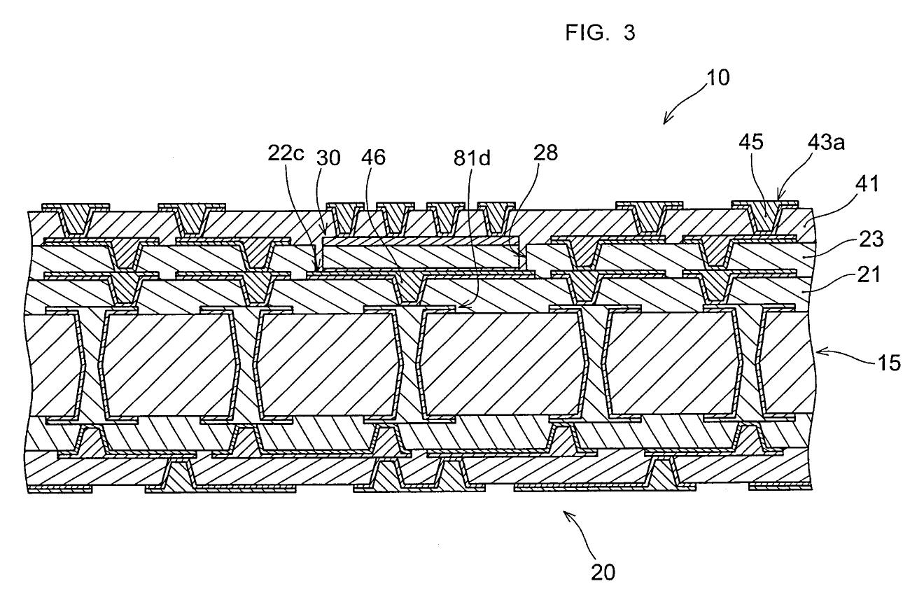

Moreover, in the present embodiment, the wiring structure (30) is provided above the first insulating layer (21), which forms the base material of the core substrate (15). However, the present embodiment is not limited to this and, as shown in FIG. 3, the wiring structure (30) may also be provided above an insulating layer forming a build-up layer. In the example illustrated in FIG. 3, the wiring structure (30) is provided above the first insulating layer (21), which is provided above the core substrate (15). In addition, similar to the example illustrated in FIG. 1A, the wiring structure (30) is provided within the opening (28), which is provided to the third insulating layer (23). Similar to the example illustrated in FIG. 1A, the fourth insulating layer (41), the second mounting pad (43a), and the third via conductor (45) are provided above the third insulating layer (23). The wiring structure (30) may also be additionally provided above the topmost insulating layer.

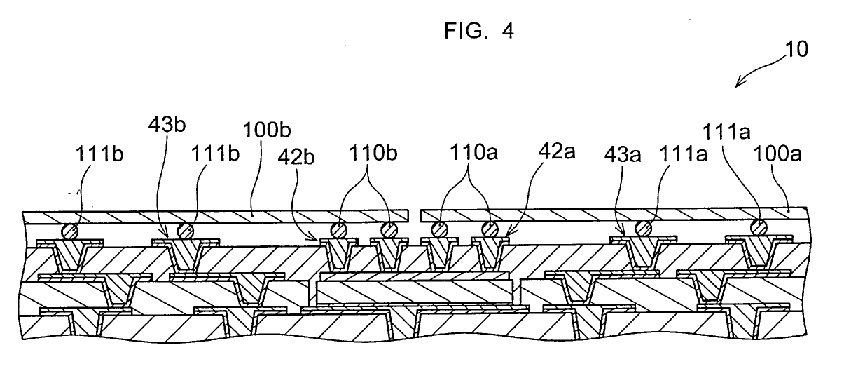

As shown in FIG. 4, semiconductor elements (100a) and (100b) are connected to the multilayer wiring board (10) of the present embodiment. The semiconductor element (100a) includes a solder bump (110a) and a solder bump (111a). The solder bump (110a) is positioned at a narrower pitch than the solder bump (111a). The solder bump (110a) is connected to the first mounting pad (42a), while the solder bump (111a) is connected to the second mounting pad (43a). Similarly, the semiconductor element (100b) includes a solder bump (110b) and a solder bump (111b). The solder bump (110b) is positioned at a narrower pitch than the solder bump (111b). The solder bump (110b) is connected to the first mounting pad (42b), while the solder bump (111b) is connected to the second mounting pad (43b). As shown in FIG. 2, the first mounting pads (42a, 42b) are connected to the conductor pad (36) by the third via conductor (44). In addition, the second conductor pattern (34a) is formed on the second conductor layer (34), the second conductor pattern (34a) electrically connecting the conductor pad (36) which is connected to the first mounting pad (42a), and the conductor pad (36) which is connected to the first mounting pad (42b). Thereby, the adjacent solder bump (110a) and solder bump (110b) are electrically connected. As shown in FIG. 1B, the second conductor patterns (34a) are provided to the wiring structure (30), the second conductor patterns (34a) respectively connecting predetermined first mounting pads (42a, 42b). As a result, an electrical connection is formed between predetermined electrodes of the semiconductor element (100a) and the semiconductor element (100b). The electrodes of the semiconductor element (100a) and the semiconductor element (100b) which are electrically connected by the second conductor pattern (34a) may be any type of electrode. For example, power supply electrodes may be connected to each other by the second conductor pattern (34a). Also, the second conductor pattern (34a) may be a signal wire transmitting a signal between the semiconductor element (100a) and the semiconductor element (100b).

As shown in FIG. 2, the wiring portion (31) of the wiring structure (30) is formed directly above the heat sink (32). Therefore, in a case where the semiconductor elements (100a, 100b) are connected to the first mounting pads (42a, 42b) on the conductor pad (30) (see FIG. 4), heat generated by the semiconductor elements (100a, 100b) is quickly dispersed. Thus, a temperature increase of the semiconductor elements (100a, 100b) is reduced. As a result, there are cases where a heat spreader or the like attached to the semiconductor elements (100a, 100b) is rendered unnecessary.

The material of the heat sink (32) is not particularly limited, so long as the material has comparatively favorable thermal conductivity. For example, a material may be used that has greater thermal conductivity than a material forming the semiconductor elements (100a, 100b), which are heat sources. In addition, metals such as copper or nanocarbon may be used. Also, insulating materials such as alumina or aluminum nitride may be used. In a case where an insulating material is used in this way, the insulating layer (37) may be omitted and the conductor layer (34) may be formed directly on the heat sink (32). Thickness of the heat sink (32) is not particularly limited, but the greater the thickness, the more heat that is rapidly dispersed.

In the present embodiment, as shown in FIG. 2, the wiring structure (30) is provided above the conductor layer (22c), which is provided above the insulating layer (21). By forming the conductor layer (22c) with a metal (for example, copper) having favorable thermal conductivity, heat release characteristics of the entire multilayer wiring board (10) are further improved. However, the wiring structure (30) may also be provided directly on the first insulating layer (21), without utilizing the conductor layer (22c). The conductor layer (22c) is preferably formed by patterning the first conductor layer (22). However, a method for forming the conductor layer (22c) is not limited to this. A metal plate formed separately from the first conductor layer (22) may also be mounted on the first insulating layer (21).

In the present embodiment, an adhesive layer (27) is interposed between the wiring structure (30) and the conductor layer (22c). As noted above, in a case where the conductor layer (22c) is omitted, the adhesive layer (27) is interposed between the wiring structure (30) and the first insulating layer (21). The wiring structure (30) is fixated to the conductor layer (22c) or the first insulating layer (21) by an adhesive forming the adhesive layer (27). The adhesive forming the adhesive layer (27) is not particularly limited. An epoxy resin, acrylic resin, silicon resin, or the like may be used, for example. An adhesive having favorable thermal conductivity is preferably used so as to transmit a greater amount of heat of the heat sink (32) with the conductor layer (22c) or the like.

In addition, in a case where the heat sink (32) is formed by a conductive material such as a metal and, as shown in FIG. 2, the heat sink (32) is provided on the conductor layer (22c), the heat sink (32) can form a shield surface due to the conductor layer (22c) being electrically connected to a ground layer. As a result, discharge of noise from the wiring portion (31) or penetration of noise to the wiring portion (31) may be reduced. This is particularly beneficial in a case where the second conductor pattern (34a) within the wiring portion (31) is a signal wire between the semiconductor element (100a) and the semiconductor element (100b), as described above.

In the embodiment illustrated in FIG. 1A, the conductor layer (22c) is connected by a through-hole conductor (26) to the conductor layer (81a) on an opposite side (second surface (F2) side of the core substrate (15)) of the first insulating layer (21). Therefore, a large amount of heat transmitted to the heat sink (32) is also conveyed to a surface on the opposite side of the first insulating layer (21). Therefore, heat release characteristics of the entire multilayer wiring board (10) are still further improved. However, the through-hole conductor (26) may also not be provided. As shown in FIG. 3, in a case where the wiring structure (30) is provided above the first insulating layer (21), for example, which forms the build-up layer, rather than the base material of the core substrate (15), the conductor layer (22c) may be connected to a lower conductor layer (81d) by a fourth via conductor (46) running through the first insulating layer (21). Accordingly, similar to the example shown in FIG. 1A, heat release characteristics of the entire multilayer wiring board (10) are still further improved.

As shown in a manufacturing method described hereafter, the wiring portion (31) of the wiring structure (30) is primarily formed in accordance with a semiconductor element manufacturing process using a semiconductor element manufacturing apparatus. Therefore, a conductor pattern may be formed on the wiring portion (31) of the wiring structure (30) at a pitch having the same degree as a placement pitch of a pad or wiring pattern formed on a semiconductor element. Accordingly, a wiring pattern may be formed on the wiring portion (31) at a pitch narrower than a substrate manufactured by a process for a typical build-up multilayer wiring board. For example, a wiring density of a substrate manufactured by a typical build-up multilayer wiring board manufacturing process has a limit of 10 μm/10 μm, in terms of line/space (L/S), which illustrates wiring density in terms of a minimum wiring width (line: L) and a minimum gap between wirings (space: S). In contrast, a conductor pattern formed on the wiring structure (30) can, for example, be formed at a fine pitch of up to 0.1 μm/0.1 μm. Specifically, the second conductor pattern (34a) is formed at a wiring density of between 1 μm/1 μm and 5 μm/5 μm, and preferably between 3 μm/3 μm and 5 μm/5 μm. In addition, a diameter of the first via conductor (35) running through the second insulating layer (33) is between 1 μm and 10 μm, and preferably between 0.5 μm and 5 μm.

In the present embodiment, as shown in FIG. 2, the first mounting pads (42a, 42b), which are connected by the solder bumps (110a, 110b) provided at a narrow pitch, and the second conductor pattern (34a), which connects the first mounting pad (42a) and the first mounting pad (42b), are formed on the wiring structure (30). By utilizing such a structure, even when the solder bumps (110a, 110b) (see FIG. 4) are provided at a pitch exceeding a pitch that can be formed by a typical build-up multilayer wiring board manufacturing process, the semiconductor elements (100a, 100b) may be connected to the multilayer wiring board (10). In addition, there is a tendency that, generally, as the wiring density increases, production yield of the build-up multilayer wiring board decreases. Therefore, even when the wiring pitch of the solder bumps (110a, 110b) are within a range which can be formed by the build-up multilayer wiring board manufacturing process, by forming a portion having high-density wiring on the wiring structure (30), production yield of the multilayer wiring board (10) may increase. As a result, there is a possibility of reducing manufacturing costs of the multilayer wiring board (10).

A top surface of the conductor pad (36) formed on the wiring structure (30) and a top surface of the third wiring pattern (24a) of the main wiring board (20) are preferably formed so as to be approximately coplanar, as shown in FIG. 2. Due to being coplanar in this way, for example, forming the top surface of the first mounting pad (42a) and the top surface of the second mounting pad (43a), which are connected to the semiconductor element (100a), are readily formed so as to be coplanar. However, the top surface of the conductor pad (36) and the top surface of the third conductor pattern (24a) may also not be formed so as to be coplanar.

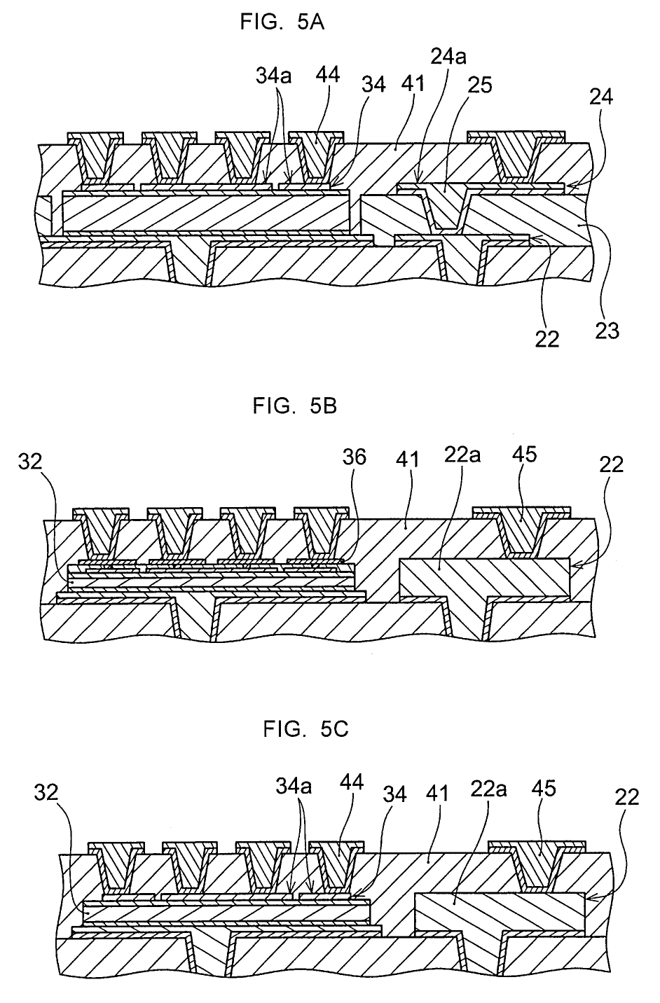

In the example illustrated in FIG. 2, the second insulating layer (33), the first via conductor (35), and the conductor pad (36) are formed on the wiring portion (31) of the wiring structure (30). However, these may also be omitted. FIG. 5A illustrates a structure of a portion corresponding to a portion shown in FIG. 2 of an example where the first via conductor (35) and the conductor pad (36) are omitted. In the example illustrated in FIG. 5A, the third via conductor (44) is connected to the second conductor pattern (34a). In addition, the second conductor layer (34) is covered by the fourth insulating layer (41). In the example illustrated in FIG. 5A, the top surface of the second conductor pattern (34a) and the top surface of the third conductor pattern (24a) are preferably formed so as to be coplanar. However, the top surface of the second conductor pattern (34a) and the top surface of the third conductor pattern (24a) may also not be formed so as to be coplanar.

In addition, in the example illustrated in FIGS. 1A and 2, the third insulating layer (23), the third conductor layer (24), and the second via conductor (25) are formed above the first conductor layer (22). However, these may also be omitted. FIG. 5B illustrates a structure of a portion corresponding to a portion shown in FIG. 2 of an example where the third insulating layer (23), the third conductor layer (24), and the second via conductor (25) are omitted. In the example illustrated in FIG. 5B, the third via conductor (45) is connected to the first conductor layer (22). In addition, the first conductor layer (22) is covered by the fourth insulating layer (41). In the example illustrated in FIG. 5B as well, the top surface of the conductor pad (36) and the top surface of the first conductor pattern (22a) may also be formed so as to be substantially coplanar by adjusting thicknesses of the heat sink (32) and the first conductor layer (22). However, a positional relationship of the top surface of the conductor pad (36) and the top surface of the first conductor pattern (22a) is not limited to this.

In addition, the second insulating layer (33), the first via conductor (35), and the conductor pad (36) as well as the third insulating layer (23), the third conductor layer (24), and the second via conductor (25) may also both be omitted. FIG. 5C illustrates a structure of a portion corresponding to the portion shown in FIG. 2 of an example of this structure. In the example illustrated in FIG. 5C, the third via conductor (44) is connected to the second conductor layer (34). In addition, the third via conductor (45) is connected to the first conductor layer (22). Also, the second conductor layer (34) and the first conductor layer (22) are covered by the fourth insulating layer (41). In this case as well, the top surface of the second conductor pattern (34a) and the top surface of the first conductor pattern (22a) may also be formed so as to be substantially coplanar by adjusting thicknesses of the heat sink (32) and the first conductor layer (22). However, a positional relationship of the top surface of the second conductor pattern (34a) and the top surface of the first conductor pattern (22a) is not limited to this.

The second conductor pattern (34a) and the conductor pad (36), which are formed on the wiring portion (31) of the wiring structure (30), are formed at an extremely high density, as noted above. Therefore, the wiring structure (30) are accurately positioned in a predetermined position of the main wiring board (20) such that the second conductor pattern (34a) and the conductor pad (36) are reliably connected to the predetermined first mounting pads (42a, 42b), respectively. In addition, in a case where the wiring structure (30) is fixated by an adhesive as described previously, the wiring structure (30) may move atop the adhesive layer (27) before the adhesive is cured, and therefore the wiring structure may not be fixated in the correct position. Therefore, a wiring structure positioning means may be provided to a bottom portion of the heat sink (32) and/or to a heat sink positioning portion of the conductor layer (22c).

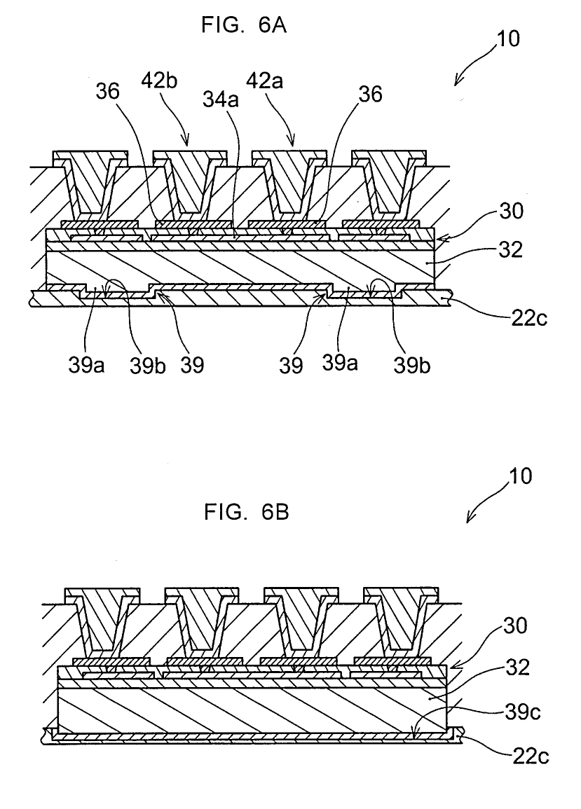

An exemplary wiring structure positioning device (39) is illustrated in FIG. 6A. A projection (39a) is provided to a rear surface of the heat sink (32). In addition, a recess (39b) engaging with the projection (39a) is provided to a front surface of the conductor layer (22c). The recess (39a) is provided at a position facing the projection (39a) when the wiring structure (30) is positioned correctly. By engaging the projection (39a) and the recess (39b), the wiring structure (30) is provided in the correct position. Also, positional drift of the wiring structure (30) prior to curing of the adhesive is prevented. As a result, the wiring structure (30) is fixated in the correct position, and the second conductor pattern (34a) and conductor pad (36) are reliably connected to the predetermined first mounting pads (42a, 42b), respectively.

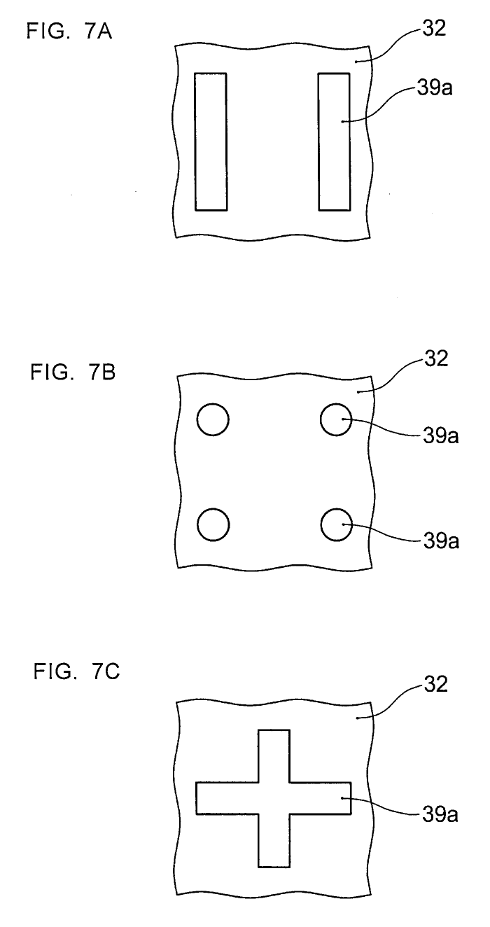

As shown in FIG. 7A to 7C, a planar shape and quantity of the projection (39a) provided to the rear surface of the heat sink (32) are not particularly limited. For example, as shown in FIG. 7A, a projection (39a) having a rectangular planar shape may be provided to a vicinity of each of a pair of opposing end portions. As shown in FIG. 7B, a projection (39a) having a circular planar shape may be provided to four corners of the rear surface of the heat sink (32). As shown in FIG. 7C, a projection (39a) having a cross-shaped planar shape may be provided to a center portion of the rear surface of the heat sink (32). Moreover, in the example illustrated in FIG. 6A, the projection (39a) is formed on the heat sink (32) side and the recess (39b) is provided to the conductor layer (22c) side; however, the projection (39a) and the recess (39b) may also each be provided to the opposite side.

Also, as shown in FIG. 6B, a recess (39c) accommodating the entire heat sink (32) in a plan view may also be provided to the conductor layer (22c). The wiring structure (30) is positioned by engaging the entire heat sink (32) with the recess (39c). Moreover, the conductor layer (22c) may be formed to be smaller than the heat sink (32) in a plan view, and the entire bottom surface except an outer peripheral portion may be depressed to provide a recess on the bottom surface of the heat sink (32). The wiring structure (30) is positioned by engaging the recess and the entire conductor layer (22c). The projection (39a) and the recess (39b, 39c) shown in FIGS. 6A, 6B, and 7A to 7C may, for example, be formed by etching a rear surface of the heat sink (32) or a front surface of the conductor layer (22c).

The wiring structure (30) and the semiconductor elements (100a, 100b) may also be electrically connected to an exterior electrical component or the like via the main wiring board (20). For example, the semiconductor element (100a) may also be electrically connected to an exterior semiconductor element via the first conductor pattern (22) and/or the third conductor pattern (24a). Similarly, the semiconductor element (100b) may also be electrically connected to an exterior semiconductor element via the fourth conductor pattern (22b) and/or the third conductor pattern (24b). In addition, for example, a wiring pattern may be formed on the fourth insulating layer (41) shown in FIG. 1A, the wiring pattern connecting the first mounting pads (42a, 42b) and the second mounting pads (43a, 43b). By doing this, the second conductor pattern (34a) within the wiring structure (30) may be electrically connected to an exterior semiconductor element via the first conductor pattern (22a), the third conductor patterns (24a, 24b), and/or the fourth conductor pattern (22b) within the main wiring board (20).

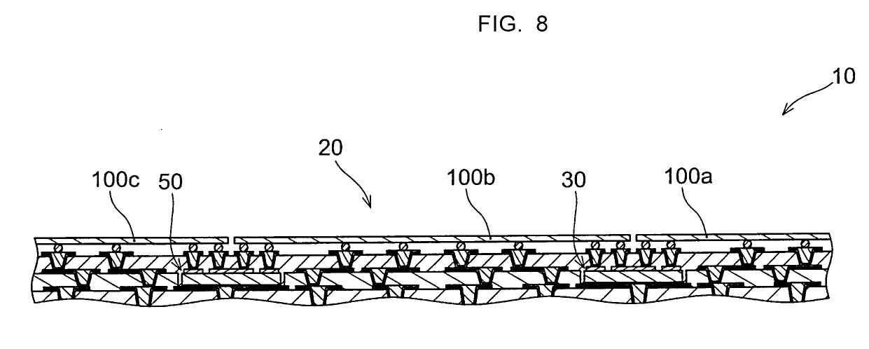

Also, as shown in FIG. 8, a second wiring structure (50) and a semiconductor element (100c) may also be provided to the opposite side of the semiconductor element (100b) from the semiconductor element (100a), and the semiconductor element (100b) may be electrically connected to the semiconductor element (100a) via the wiring structure (30), and also electrically connected to the semiconductor element (100c) via the wiring structure (50).

In addition, in the present embodiment, as shown in FIG. 1A, three conductor layers (81a to 81c) and two insulating layers (82a, 82b) are alternatingly laminated on the second surface (F2) of the core substrate (15). Via conductors (83a, 83b) are provided to the insulating layers (82a, 82b), respectively. The conductor layer (81a) and conductor layer (81b) are connected by the via conductor (83a). Similarly, the conductor layer (81b) and the conductor layer (81c) are connected by the via conductor (83b). However, a number of insulating layers and conductor layers less than, or greater than, the number of insulating layers and conductor layers shown in FIG. 1A may be laminated on the second surface (F2) of the core substrate (15).

In the present embodiment, the through-hole conductor (26) running through the core substrate (15) is formed by filling a through-hole (26a) provided to the core substrate (15) with a conductor such as a metal. In the present embodiment, the first conductor layer (22) and the conductor layer (81a) are connected by the through-hole conductor (26).

In the present embodiment, the first insulating layer (21) (base material of the core substrate) is formed by impregnating a resin in a core material. The first insulating layer (21) is a glass epoxy substrate formed by impregnating an epoxy resin in a core material formed by glass fiber cloth. However, the present invention is not limited to this, and any insulating material may be used for the first insulating layer (21).

Any of the first to third via conductors (25, 35, 44, 45) and the via conductors (83a, 83b) are field conductors formed by filling a via hole provided to an insulating layer with copper formed by plating or the like. However, the present invention is not limited to this, and any of the various via conductors may also be a conformal conductor.

The third and fourth insulating layers (23, 41) and the insulating layers (82a, 82b) are formed by epoxy resin in the present embodiment. However, the present invention is not limited to this, and any material may be used.

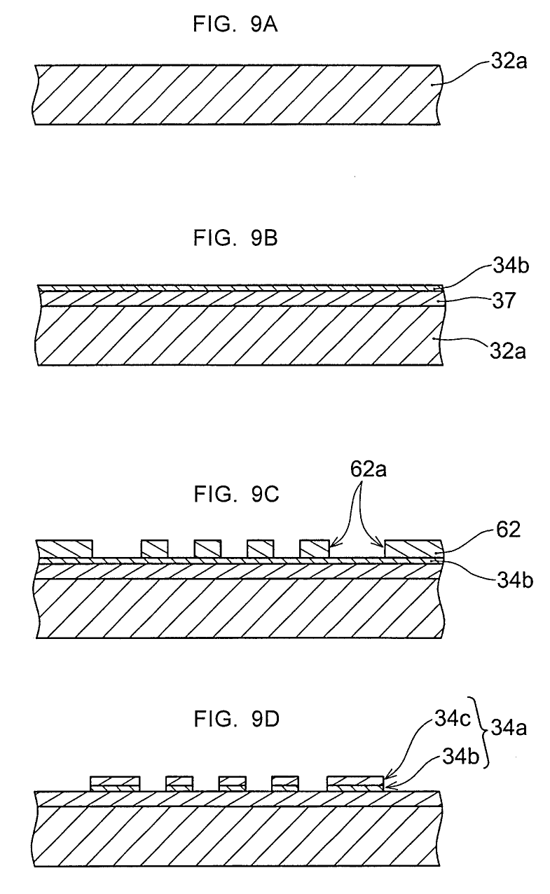

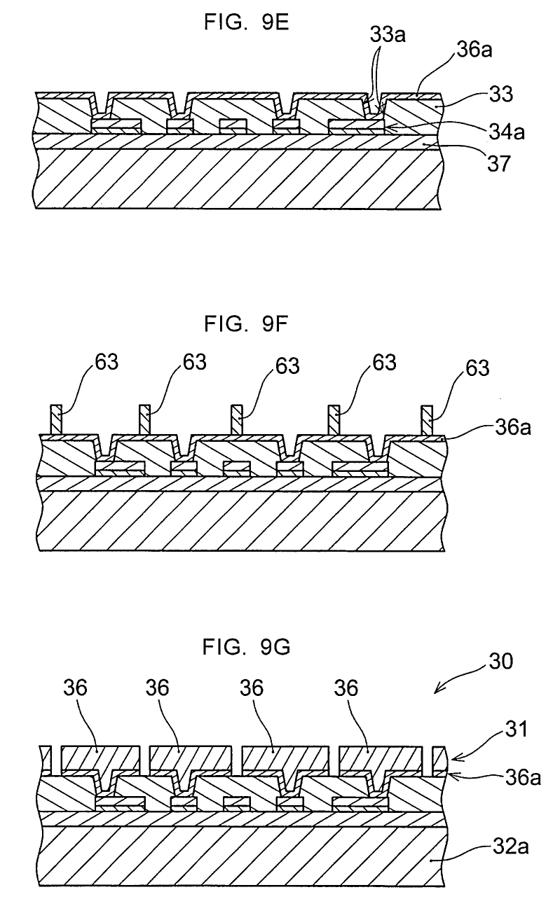

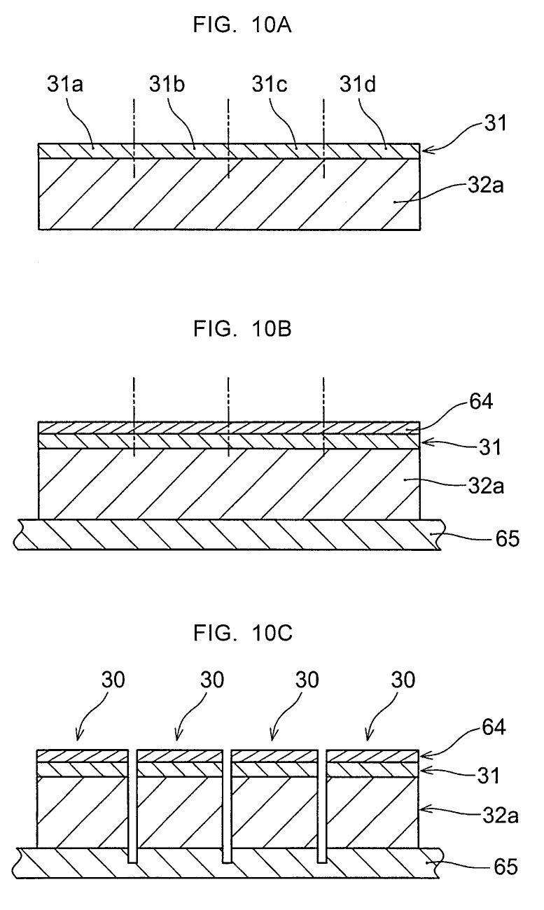

Next, a description is given of an exemplary method for manufacturing the multilayer wiring board (10) according to the present embodiment. The method for manufacturing the multilayer wiring board (10) according to the present embodiment is formed by a method for manufacturing the wiring structure (30) and a method for manufacturing the main wiring board (20), which includes attaching the wiring structure (30) to the main wiring board (20). First, the method for manufacturing the wiring structure (30) is described below with reference to FIG. 9A to 9G and FIG. 10A to 10C.

First, as shown in FIG. 9A, a wafer (32a) formed from a material having favorable heat release characteristics (such as copper, for example) is prepared. In the present embodiment, wiring portions (31) of the wiring structure (30) are formed on one wafer (32a). FIG. 9A to 9G illustrate only portions corresponding to a single wiring structure (30). The wafer (32a) is divided after formation of the wiring portion (see FIG. 2), and each forms a heat release member (32) of the wiring structure (30).

Next, the wiring portion (31) (see FIG. 2) is formed above the wafer (32a). The wiring portion (31) is formed by the semiconductor element manufacturing process, as described above. Specifically, as shown in FIG. 9B, a fifth insulation layer (37) is first formed on the wafer (32a). The fifth insulation layer (37) is formed by either laminating an insulating material pre-formed in a film shape onto the wafer (32a), or by applying a liquid insulating material onto the wafer (32a) and heat treating it. However, the fifth insulating layer (37) may also be formed by a different method. Next, a seed layer (34b) is formed on the fifth insulating layer (37) using a sputtering method or the like. Titanium, copper, or the like may be used as a material for the seed layer (34b). However, the material for the seed layer (34b) is not limited to these.

Next, as shown in FIG. 9C, a resist film (62) having a predetermined pattern is formed on the seed layer (34b). Specifically, a photosensitive resist film (62) is laminated onto the seed layer (34b). Next, the resist film (62) is exposed to light that is transmitted through a mask (not shown in the drawings) formed in a predetermined pattern. The resist film (62) is then developed and patterned to the predetermined pattern.

Next, a conductor pattern is formed on the fifth insulating layer (37). Specifically, an upper conductor layer (34c) is first formed by a plating method, for example, on the seed layer (34b) within an opening (62a) of the resist film (62) shown in FIG. 9C. The upper conductor layer (34c) may be a layer in which an electroless copper plating layer, an electrolysis copper plating layer, or an electroless copper plating layer and an electrolysis copper plating layer are laminated. Next, the resist film (62) is peeled away. The seed layer (34b) exposed by peeling away the resist film (62) is removed by etching. As a result, the second conductor pattern (34a) shown in FIG. 9D is formed. In the present embodiment, the second conductor pattern (34a) is formed of a laminate body of two layers, the seed layer (34b) and the upper conductor layers (34c). The second conductor pattern (34a) is formed at an extremely fine pitch. The second conductor pattern (34a) is formed with a line/space of, for example, between 1 μm/1 μm and 5 μm/5 μm, and preferably at a wiring density of between 3 μm/3 μm and 5 μm/5 μm.

Next, as shown in FIG. 9E, the second insulating layer (33) is formed above the fifth insulating layer (37) and the second conductor pattern (34a). The second insulating layer (33) is formed using a method similar to that of the fifth insulating layer (37). A photosensitive polyimide, for example, is used in the second insulating layer (33), but the present invention is not limited to this. Next, the second insulating layer (33) is exposed to light that is transmitted through a mask (not shown in the drawings) having an opening at a predetermined position. Then the second insulating layer (33) is developed and a via hole (33a) is provided to a predetermined position of the second insulating layer (33). Next, a seed layer (36a) is formed on the second insulating layer (33), as well as on an inner wall surface and bottom surface of the via hole (33a), using a sputtering method or the like.

Next, as shown in FIG. 9F, a resist film (63) having a predetermined pattern is formed on the seed layer (36a). The resist film (63) is formed using a method similar to that of the resist film (62).

Next, as shown in FIG. 9G, the conductor pad (36) is formed on the seed layer (36a). The conductor pad (36) is formed using a method similar to that of the second conductor pattern (34a). Thereafter, etching or grinding may also be performed on a rear surface of the wafer (32a). As a result, the wiring portion (31) of the wiring structure (30) is completed. Moreover, in a case where the wiring structure (30) is manufactured in a structure such as in the example shown in FIGS. 5A and 5C, processes from formation of the second insulating layer (33) to formation of the conductor pad (36) are omitted.

The wiring portion (31) shown in FIG. 9G is, in the present embodiment, formed in a state where wiring portions (31) are aligned on the wafer (32a), as shown in FIG. 10A. FIG. 10A to 10C respectively illustrate a portion corresponding to four of these wiring portions (31a to 31d). Moreover, in FIG. 10A to 10C, depictions of the fifth insulating layer (37), the second conductor pattern (34a), and the like which form the wiring portion (31) are omitted. Processes related to the wiring structure (30) after formation of the wiring portion (31) are described with reference to FIGS. 10B and 10C.

As shown in FIG. 10B, a protective film (64) protecting the wiring portion (31) is laminated onto the wiring portion (31) during manufacture of the wiring structure (30). Next, a dicing tape (65) supporting the laminate structure (30) is laminated on the rear surface of the wafer (32a). An adhesive may also be laminated between the dicing tape (65) and the wafer (32a). Moreover, laminating the protective film (64) may be omitted.

Next, as shown in FIG. 10C, the wafer (32a) and the fifth insulating layer (37) and the like formed on the wiring portion (31) are cut at predetermined positions by a dicing saw, for example. As a result, the wiring structure (30) divided into individual pieces is obtained. When attaching the wiring structure (30) to the main wiring board (20), the wiring structure (30) is picked up from the dicing tape (65).

Next, a method for manufacturing the main wiring board (20) of the multilayer wiring board (10) according to the present embodiment is described with reference to FIG. 11A to 11H.

First, as shown in FIG. 11A, the substrate (core substrate) (15) is prepared. A base material of the substrate (15) (first insulating layer (21) in the present embodiment) is, for example, a glass epoxy material formed by impregnating an epoxy resin in a core material formed by glass fiber cloth. However, the present invention is not limited to this, and any insulating material may be used. Copper foil (221) is provided to each of the first surface (F1) on one side of the substrate (15) and the second surface (F2) on another side of the substrate (15).

Next, using a CO₂ laser for example, a laser bombards the substrate (15) from the first surface (F1) side and the second surface (F2) side of the substrate (15) alternately or simultaneously. Thereby, as shown in FIG. 11B, the through-hole (26a) is formed in the substrate (15). Thereafter, the through-hole (26a) preferably undergoes a desmearing treatment. By desmearing, unnecessary conduction (shorts) are inhibited. In addition, a front surface of the copper foil (221) may be blackened prior to laser exposure in order to increase laser light absorption efficiency.

Next, using a panel plating method for example, a copper electroless plating film (26b), for example, is formed on the first surface (F1) and second surface (F2) of the substrate (15) and on the inner wall of the through-hole (26a). Next, an electrolysis plating film (26c) is formed by electrolysis plating with the electroless plating film (26b) as a seed layer. Thereby, the through-hole (26a) is filled by the electrolysis plating film (26c), and the through-hole conductor (26) is formed. In addition, the first conductor layer (22) is formed by the copper foil (221), the electroless plating film (26b), and the electrolysis plating film (26c) on the substrate (15).

Next, an etching resist having a predetermined pattern is formed on the electrolysis plating film (26c), and portions of the electrolysis plating film (26c) not covered by the etching resist, the electroless plating film (26b), and the copper foil (221) are removed. Thereafter, as shown in FIG. 11C, the first conductor pattern (22a) is formed by removing the etching resist. A depiction of the copper foil (221) is omitted in FIG. 11C to 11H. In addition, a depiction of the second surface (F2) side of the substrate (15) is also omitted in FIG. 11C to 11H. The second surface (F2) side of the substrate (15) is provided with an insulating layer, a conductor layer, and a via conductor in a manner similar to the first surface (F1) side, up to the processes shown in FIG. 11E. Also, in the processes shown in FIG. 11F to 11H, the second surface (F2) side of the substrate (15) is not processed.

Next, as shown in FIG. 11D, the third insulating layer (23) is provided on the front surface of the substrate (15). The third insulating layer (23) is cured by heating. A material of the third insulating layer (23) is not particularly limited, but a heat-curable epoxy resin or the like is preferably used.

Next, as shown in FIG. 11E, the second via conductor (25) and third conductor pattern (24a) are formed on an interior of the third insulating layer (23) and on the third insulating layer (23). Specifically, using a CO₂ laser for example, a via hole is formed in the third insulating layer (23). Then, an electroless plating film (25b) of copper, for example, is formed on a front surface of the third insulating layer (23) and on an inner wall of the via hole. Next, a plating resist having a predetermined pattern is formed on the electroless plating film (25b). Then, an electrolysis plating film (25c) is formed on areas not covered by the plating resist. Next, the plating resist is removed using a predetermined stripping fluid. Moreover, the electroless plating film (25b) in areas exposed by removing the plating resist is removed by etching. As a result, as shown in FIG. 11E, the second via conductor (25) and the third conductor pattern (24a) are formed.

Next, as shown in FIG. 11F, an opening (28) accommodating the wiring structure (30) is formed on the third insulating layer (23). Specifically, the third insulating layer (23) in an area where the opening (28) is provided is removed by either grinding with a drill, or being bombarded by laser light, thus forming the opening (28). The first conductor layer (22), where the wiring structure (30) is provided, may also be exposed by formation of the opening (28).

Moreover, in a case where the main wiring board (10) according to the present embodiment is formed as in the example shown in FIGS. 5B and 5C, the above-described processes from formation of the third insulating layer (23) to formation of the opening (28) are omitted.

In addition, as shown in FIG. 3, in a case where the wiring structure (30) is formed on an insulating layer forming a build-up layer, first the conductor layer (81d) is formed onto a core substrate using a method similar to the above-described method for forming the first conductor layer (22). Next, the first insulating layer (21), first conductor pattern (22a), and fourth via conductor (46) are formed above the conductor layer (81d) using a method similar to the above-described method for forming the third insulating layer (23), the third conductor pattern (24a), and the second via conductor (25). Thereafter, processes following formation of the third insulating layer (23) and the like are performed using a method similar to the above-described method.

Next, the wiring structure (30) fabricated to a state shown in FIG. 10C is attached to the opening (28). Specifically, the separated wiring structure (30) is picked up from the dicing tape (65), an adhesive force of which is weakened by exposure to ultraviolet rays for example. In a case where adhesive material or the like is on the rear surface of the wiring structure (30), the wiring structure (30) is arranged in a predetermined position within the opening (28) without further modification. In a case where no adhesive material or the like is on the rear surface, an adhesive material or the like is supplied to the rear surface of the wiring structure (30) or to an interior of the opening (28) and the wiring structure (30) is arranged in the predetermined position. The adhesive may also be cured by heating. In addition, positioning of the wiring structure (30) is facilitated when the positioning device (39) is provided, several examples of which are illustrated in FIGS. 6A, 6B, and 7A to 7C.

Next, as shown in FIG. 11G, the fourth insulating layer (41) is laminated onto the wiring structure (30), the third conductor pattern (24a), and the third insulating layer (23). The fourth insulating layer (41) may also be cured by heating. A material of the fourth insulating layer (41) is not particularly limited, but a polyimide, a heat-curable epoxy resin, or the like is preferably used.

Next, a via hole, an electroless plating film, and an electrolysis plating film are formed using a method similar to the above-described method for forming the second via conductor (25) and the third conductor pattern (24a). The third via conductors (44, 45), the first mounting pads (42a, 42b), and the second mounting pads (43a, 43b) are formed as shown in FIG. 11H. As a result, the multilayer wiring board (10) having the structure illustrated in FIG. 1 is completed.

Accompanying increased integration of semiconductor elements such as an IC, a number of electrodes on a semiconductor chip increases and a placement pitch of the electrodes becomes narrower. Therefore, a multilayer wiring board is sought for mounting a semiconductor chip in which mounting pads for the semiconductor chip and a wiring pattern are formed at a narrow pitch.

In a multilayer wiring board described in Japanese Patent Publication No. 2013-214578, a semiconductor chip is merely connected to a main wiring board and an auxiliary wiring board formed of a thin metal plating film and a resin insulating layer. Therefore, when the semiconductor chip generates heat during operation, the semiconductor chip may overheat.

A multilayer wiring board according to an embodiment of the present invention is capable of connecting a semiconductor element having narrow pitch with favorable heat release characteristics.

A multilayer wiring board according to an embodiment of the present invention includes a first insulating layer; a first conductor pattern formed above the first insulating layer; and a wiring structure provided above the first insulating layer adjacent to the first conductor pattern and having a heat sink and a second conductor pattern formed above the heat sink.

A multilayer wiring board according to an embodiment of the present invention has favorable heat release characteristics due to the multilayer wiring board including a wiring structure that includes a heat sink.

Obviously, numerous modifications and variations of the present invention are possible in light of the above teachings. It is therefore to be understood that within the scope of the appended claims, the invention may be practiced otherwise than as specifically described herein.

What is claimed is:

1. A multilayer wiring board, comprising:
a first insulating layer;
a plurality of first conductor patterns formed on the first insulating layer; and
a wiring structure formed on the first insulating layer and comprising a heat sink and a plurality of second conductor patterns formed on the heat sink such that the wiring structure is positioned adjacent to the plurality of first conductor patterns on the first insulating layer.

2. A multilayer wiring board according to claim 1, further comprising:
a conductor layer formed on the first insulating layer,
wherein the wiring structure is formed on the conductor layer.

3. A multilayer wiring board according to claim 1, further comprising:
a semiconductor component connected to the plurality of first conductor patterns on the first insulating layer and the plurality of second conductor patterns of the wiring structure.

4. A multilayer wiring board according to claim 1, wherein the plurality of first conductor patterns is formed such that surfaces of the first conductor patterns and surfaces of the second conductor patterns are on a same plane.

5. A multilayer wiring board according to claim 1, wherein the wiring structure includes a second insulating layer covering the plurality of second conductor patterns, a plurality of first via conductors formed through the second insulating layer such that the plurality of first via conductors is connected to the plurality of second conductor patterns, respectively, and a conductor pad structure formed on the second insulating layer such that the conductor pad structure is connected to the plurality of first via conductors.

6. A multilayer wiring board according to claim 5, wherein the plurality of first conductor patterns is formed such that surfaces of the first conductor patterns and a surface of the conductor pad structure are on a same plane.

7. A multilayer wiring board according to claim 1, further comprising:
a third insulating layer formed on the plurality of first conductor patterns and the first insulating layer;
a plurality of second via conductors formed through the third insulating layer such that the plurality of second via conductors is connected to the plurality of first conductor patterns, respectively; and
a plurality of third conductor patterns formed on the third insulating layer such that the plurality of third conductor patterns is connected to the plurality of second via conductors, respectively,
wherein the wiring structure is positioned in an opening portion formed in the third insulating layer.

8. A multilayer wiring board according to claim 7, wherein the plurality of third conductor patterns is formed such that surface of the second conductor patterns and surfaces of the third conductor patterns are on a same plane.

9. A multilayer wiring board according to claim 5, further comprising:
a third insulating layer formed on the plurality of first conductor patterns and the first insulating layer;
a plurality of second via conductors formed through the third insulating layer such that the plurality of second via conductors is connected to the plurality of first conductor patterns, respectively; and
a plurality of third conductor patterns formed on the third insulating layer such that the plurality of third conductor patterns is connected to the plurality of second via conductors, respectively,
wherein the wiring structure is positioned in an opening portion formed in the third insulating layer.

10. A multilayer wiring board according to claim 9, wherein the plurality of third conductor patterns is formed such that surfaces of the second conductor patterns and surfaces of the third conductor patterns are on a same plane.

11. A multilayer wiring board according to claim 7, further comprising:
a fourth insulating layer covering the plurality of second conductor patterns and the plurality of third conductor patterns;
a plurality of third via conductors formed through the fourth insulating layer such that the plurality of third via conductors is connected to the plurality of second conductor patterns and the plurality of third conductor patterns, respectively; and
a plurality of mounting pads formed on the fourth insulating layer such that the plurality of mounting pads is connected to the plurality of third via conductors, respectively, and positioned to mount a semiconductor component.

12. A multilayer wiring board according to claim 11, wherein the plurality of mounting pads includes a plurality of first mounting pads connected to the plurality of second conductor patterns, respectively, and a plurality of second mounting pads connected to the plurality of third conductor patterns, respectively, and the plurality of mounting pads is formed such that an interval between the first mounting pads is smaller than an interval between the second mounting pads.

13. A multilayer wiring board according to claim 7, wherein the plurality of second conductor patterns of the wiring structure is connected to the plurality of third conductor patterns through wiring formed above the wiring structure such that the plurality of second conductor patterns is electrically connected to an external semiconductor component through the wiring and the plurality of third conductor patterns.

14. A multilayer wiring board according to claim 7, further comprising:
an uppermost insulating layer,
wherein the wiring structure is positioned in the uppermost insulating layer.

15. A multilayer wiring board according to claim 1, wherein the heat sink of the wiring structure comprises a heat sink plate comprising one of a metal material and a nanocarbon material, and the wiring structure includes a fifth insulating layer formed on the heat sink plate such that the second conductor pattern is formed on the fifth insulating layer.

16. A multilayer wiring board according to claim 15, wherein the heat sink plate of the heat sink comprises a copper plate.

17. A multilayer wiring board according to claim 1, wherein the heat sink comprises a material having a thermal conductivity which is greater than a thermal conductivity of a semiconductor material.

18. A multilayer wiring board according to claim 1, further comprising:
an adhesive layer interposed between the first insulating layer and the wiring structure.

19. A multilayer wiring board according to claim 1, further comprising:
a plurality of fourth conductor patterns formed on the first insulating layer,
wherein the plurality of second conductor patterns forms signal wiring configured to connect a first semiconductor component between the plurality of first conductor patterns and the plurality of second conductor patterns and signal wiring configured to connect a second semiconductor component between the plurality of second conductor patterns and the plurality of fourth conductor patterns.

20. A multilayer wiring board according to claim 2, wherein the conductor layer is electrically connected to a grounding layer.
